(19) United States
(12) Patent Application Publication
(10) Pub. No.: US 2026/0282567 A1
(43) Pub. Date: Sep. 17, 2026

(54) Displays with Pinhole Openings

(71) Applicant: Apple Inc., Cupertino, CA (US)

(72) Inventors: Shyuan Yang, San Jose, CA (US); Abbas Jamshidi Roudbari, Saratoga, CA (US); Cheng-Chih Hsieh, Santa Clara, CA (US); Conrad Corbella Bagot, San Francisco, CA (US); Jean-Pierre S Guillou, La Jolla, CA (US); Mao-Hsun Cheng, San Diego, CA (US); Ricardo A Peterson, San Jose, CA (US); Ting-Kuo Chang, San Jose, CA (US); Warren S Rieutort-Louis, Cupertino, CA (US); Yi Qiao, San Jose, CA (US); Yuchi Che, Santa Clara, CA (US); Zhizhen Ma, San Jose, CA (US)

(21) Appl. No.: 19/530,185

(22) Filed: Feb. 4, 2026

Related U.S. Application Data
(60) Provisional application No. 63/772,307, filed on Mar. 14, 2025.

(51) Int. Cl. H10F 39/10; H10H 29/80

(52) U.S. Cl. CPC H10F 39/103; H10H 29/8321; H10H 29/8323

(57) ABSTRACT

An electronic device may include a camera or other sensor that operates through a display. The display may include an array of pixels, and each pixel may include an emissive subpixel and a thin-film transistor (TFT) subpixel that drives the emissive subpixel of that pixel. To minimize interference with the light that passes through the display, the display may be modified to have one or more holes/windows. The hole(s) may be formed by removing the TFT subpixel of one or more pixels in the display, while retaining the emissive subpixel(s) of the one or more pixels. Anodes of the emissive subpixel(s) may be formed from transparent material to improve the transparency of the hole. In this way, light may pass through the hole, but the hole may maintain the uniformity of the display.

This application claims the benefit of U.S. provisional patent application No. 63/772,307, filed Mar. 14, 2025, which is hereby incorporated by reference herein in its entirety.

### BACKGROUND

This relates generally to electronic devices, and, more particularly, to electronic devices with displays.

Electronic devices often include displays. For example, an electronic device may have a light-emitting diode (LED) display based on light-emitting diode pixels. In this type of display, each pixel includes a light-emitting diode and circuitry for controlling application of a signal to the light-emitting diode to produce light.

There is a trend towards borderless electronic devices with a full-face display. Additionally, these devices may include sensors such as cameras, ambient light sensors, and proximity sensors to provide other device capabilities.

### SUMMARY

An electronic device may include a plurality of pixels arranged in a light-emitting area. Each one of the plurality of pixels may include an emissive subpixel and a thin-film transistor subpixel that controls the emissive subpixel of that pixel. A hole may be formed in the plurality of pixels that includes a subset of the emissive subpixels, including anodes of the subset of the emissive subpixels, and that is free of thin-film transistor subpixels. An optical sensor may operate through the hole in the plurality of pixels.

A display may include a plurality of pixels arranged in a light-emitting area. Each one of the plurality of pixels may include an emissive subpixel and a thin-film transistor subpixel that controls the emissive subpixel of that pixel. A window may be formed in the plurality of pixels. The window may be formed from a subset of the pixels that includes respective emissive subpixels and that does not include thin-film transistor subpixels. The window may be surrounded by other pixels of the plurality of pixels.

An electronic device may include a display that includes a plurality of pixels arranged in a light-emitting area. Each one of the plurality of pixels may include an emissive subpixel and a thin-film transistor subpixel that controls the emissive subpixel of that pixel. A window may be formed in the plurality of pixels. The window may be formed from a subset of the pixels that includes respective emissive subpixels and respective anodes and that does not include thin-film transistor subpixels. A sensor may operate through the window.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a top view of an illustrative display in accordance with some embodiments.

FIG. 4 is a side view of an illustrative display that includes a hole/window for an underlying sensor in accordance with some embodiments.

FIG. 5A is a top view of an illustrative pixel array that includes a hole for an underlying sensor in accordance with some embodiments.

FIG. 5B is a top view of an illustrative pixel array that includes pixels with laterally shifted anodes to accommodate a hole for an underlying sensor in accordance with some embodiments.

FIG. 6A is a top view of an illustrative pixel array that includes a hole with a pixel that has both an emissive subpixel and a thin-film transistor (TFT) subpixel removed in accordance with some embodiments.

FIG. 6B is a side view of an illustrative display that includes a hole with a pixel that has both an emissive subpixel and a thin-film transistor (TFT) subpixel removed in accordance with some embodiments.

FIG. 7 is a top view of an illustrative pixel array having modified pixels and a hole in the modified pixels in accordance with some embodiments.

FIGS. 8A-8C are illustrative patterns of one or more holes in a display in accordance with some embodiments.

### DETAILED DESCRIPTION

An electronic device may include a display, such as at a front face of the device. For example, the display may extend over an entirety or nearly an entirety of the front face. In some embodiments, it also may be desirable to provide the device with a camera at the front face. To accommodate the camera while maintaining the display across the front face, the camera may be incorporated in the device under the display. In other words, the camera may operate through the display.

To reduce diffraction and image distortion in the camera due to the overlying display, the display may be modified to include a hole/window that overlaps the camera. The hole may be an opening in which one or more subpixels are removed. The anodes of the removed subpixel(s) and/or surrounding subpixels may be maintained for emission and/or shifted, if desired, which may maintain a uniform appearance of the display. The anodes may be formed from transparent material, if desired, to improve the transparency of the hole for the underlying camera. In this way, the display may be modified to include one or more holes for one or more underlying cameras.

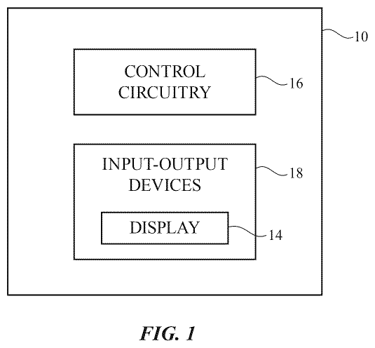

An illustrative electronic device of the type that may be provided with a display having a hole/window for an underlying camera is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wristwatch device, a pendant device, a headphone or earpiece device, an augmented reality (AR) headset and/or virtual reality (VR) headset, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), and/or other memory. Processing circuitry in control circuitry 16 may be used to control the operation of device 10. The processing circuitry may be based on one or more microprocessors, microcontrollers, digital signal processors, baseband processors, power management units, audio chips, application specific integrated circuits, and/or other components.

Input-output devices in device 10, such as input-output devices 18, may be used to allow data to be supplied to device 10 and to allow data to be provided from device 10 to external devices or to one or more users of device 10. Input-output devices 18 may include buttons, joysticks, scrolling wheels, touch pads, keypads, keyboards, microphones, speakers, tone generators, vibrators, cameras, sensors, light-emitting diodes and other status indicators, data ports, and/or other suitable input-output devices. A user can control the operation of device 10 by supplying commands through input-output devices 18 and may receive status information and other output(s) from device 10 using the output devices of input-output devices 18.

Input-output devices 18 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Display 14 may be an organic light-emitting diode display, a display formed from an array of discrete light-emitting diodes each formed from a crystalline semiconductor die (e.g., a microLED display), a liquid crystal display, or any other suitable type of display. Configurations in which the pixels of display 14 include light-emitting diodes are sometimes described herein as an example. This is, however, merely illustrative. Any suitable type of display may be used for device 10, if desired.

Control circuitry 16 may be used to run software on device 10 such as operating system code and applications. During operation of device 10, the software running on control circuitry 16 may display images on display 14.

In some embodiments, electronic device 10 may be a wristwatch device. Display 14 of the wristwatch device may be positioned in a housing. A wristwatch strap may be coupled to the housing. In other embodiments, electronic device 10 may be a head-mounted device with display 14 positioned in a housing coupled to a headband or other head-mounted support structure. Alternatively, device 10 may be a cellular telephone or table with display 14 in a housing.

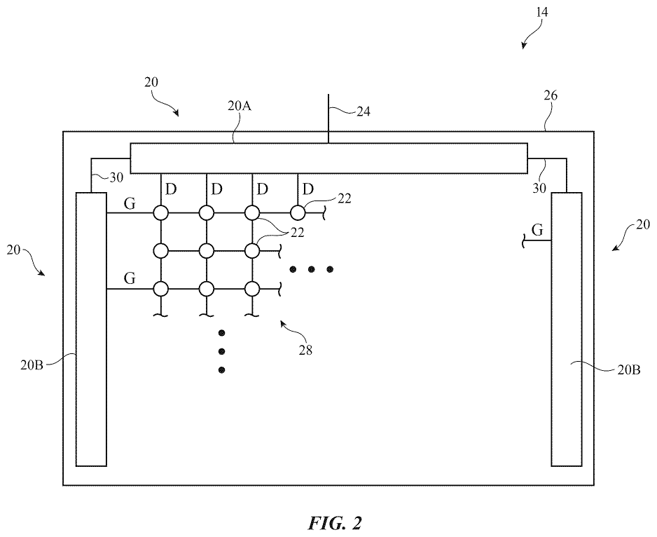

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, composite films that include polymer and inorganic materials, metallic foils, etc.

Display 14 may have an array of pixels 22, such as pixel array 28, for displaying images for a user. Pixels 22 in array 28 may be arranged in rows and columns. The edges of array 28 (sometimes referred to as active area 28 herein) may be straight or curved (e.g., each row of pixels 22 and/or each column of pixels 22 in array 28 may have the same length, or rows and/or columns in array 28 may have different lengths). There may be any suitable number of rows and columns in array 28 (e.g., ten or more, one hundred or more, or one thousand or more rows and/or columns.). Display 14 may include pixels 22 of different colors. As an example, display 14 may include red pixels, green pixels, and blue pixels. If desired, a backlight unit may provide backlight illumination for display 14.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 in an inactive area of the display as shown in FIG. 2. Gate driver circuitry 20B may include gate drivers and emission drivers, as illustrative examples.

As shown in FIG. 2, display driver circuitry 20A (e.g., one or more display driver integrated circuits, thin-film transistor circuitry, and/or other circuitry) may contain communications circuitry for communicating with system control circuitry over signal path 24. Path 24 may be formed from traces on a flexible printed circuit or other cable. The control circuitry may be located on one or more printed circuits in electronic device 10. During operation, the control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. However, this is merely illustrative. Display driver circuitry 20A may be located at both the top and bottom of display 14 or in other portions of device 10.

To display the images on pixels 22, display driver circuitry 20A may supply corresponding image data to data lines D (e.g., vertical signal lines) while issuing control signals to supporting display driver circuitry such as gate driver circuitry 20B over signal paths 30. With the illustrative arrangement of FIG. 2, data lines D run vertically through display 14 and are associated with respective columns of pixels 22. During compensation operations, column driver circuitry 20 may use paths such as data lines D to supply a reference voltage to pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, or emission control lines herein) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals). The number of horizontal signal lines in each row may be determined by the number of transistors in the display pixels 22 that are being controlled independently by the horizontal signal lines. Display pixels of different configurations may be operated by different numbers of control lines, data lines, power supply lines, etc.

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and gate driver circuitry 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

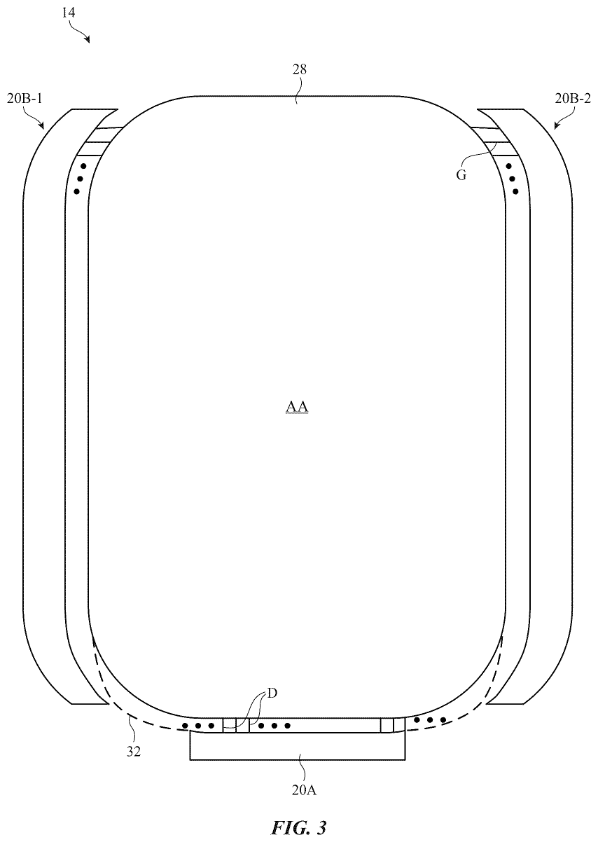

FIG. 3 shows a top view of an illustrative display with gate driver circuitry. Gate driver circuitry 20B may be formed along one or more edges of display 14. FIG. 3 shows an example where gate driver circuitry 20B is formed on first and second opposing sides of pixel array 28 (sometimes referred to as an active area AA). In other words, first gate driver circuitry 20B-1 is formed on the left side of the active area AA and second gate driver circuitry 20B-2 is formed on the right side of the active area AA.

Gate driver circuitry 20B-1 and 20B-2 may be configured to supply control signals to each pixel in the display. For example, gate driver circuitry 20B-1 and 20B-2 may supply control signals such as scanning control signals and emission control signals to the gates of transistors within each pixel (e.g., each pixel 22 of FIG. 2). Gate driver circuitry 20B-1 and 20B-2 may each contain a shift register formed from a chain of register circuits. Each register circuit may supply control signals (e.g., switching transistor control signals, emission enable signals, etc.) to a corresponding row of pixels. During operation, control circuitry 16 (e.g., using display driver circuitry 20A) may initiate propagation of a control pulse through the shift register. As the control pulse propagates through the shift register, each gate line may be activated in sequence, allowing successive rows of pixels 22 to be loaded with data from data lines D. Each register circuit may be referred to as a stage of the shift register.

In the example of FIG. 3, active area AA has a rectangular shape with rounded corners. This example is merely illustrative and in general the active area may have any desired shape.

As shown, the display also includes display driver circuitry 20A. Display driver circuitry 20A may supply corresponding image data to data lines D (e.g., vertical signal lines). Each data line D may be coupled to a respective column of pixels within the pixel array 28. However, as shown in FIG. 3, the width of display driver circuitry 20A may be less than the width of the active area AA. Accordingly, to provide data to all of the pixel columns, a fanout region 32 is used. In the fanout region, data lines D are spread out from display driver circuitry 20A to reach all of the columns in the pixel array. With the data line fanout region, the data lines are coupled to pixel columns in the rounded corner areas of the display.

In the arrangement of FIG. 3, gate driver circuitry 20B-1 and 20B-2 and data line fanout region 32 are all formed in the inactive area of the display (e.g., an area of the display without pixels). However, this is merely illustrative. In some embodiments, to reduce the size of the inactive area, gate driver circuitry 20B-1, gate driver circuitry 20B-2, and/or data line fanout region 32 may be at least partially formed in the active area of the display.

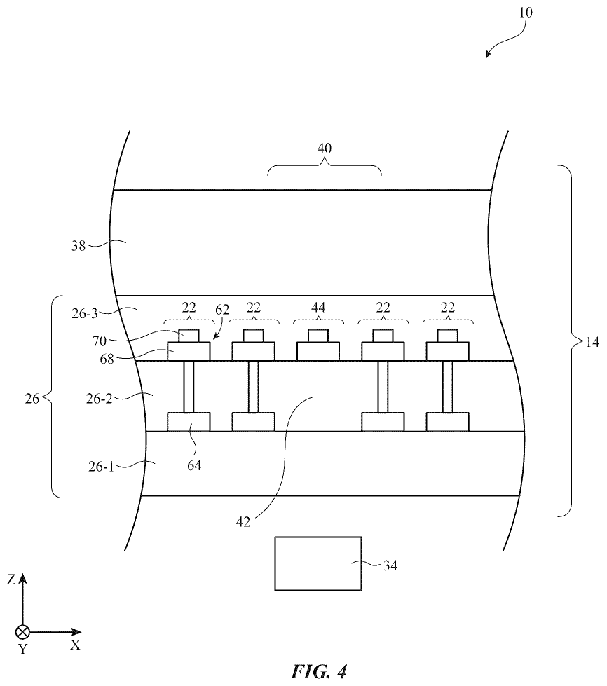

In some embodiments, it may be desirable to include a sensor, such as a camera, under display 14. To allow light to pass to the underlying camera or other sensor without diffracting or otherwise distorting the light, a window may be formed in display 14. For example, a hole (e.g., a pinhole opening) may be formed by removing portion(s) of one or more of the pixels of pixel array 28. An illustrative side view of pixels having removed portions is shown in FIG. 4.

As shown in FIG. 4, display 14 may include an array of display pixels 22 (also referred to as pixels 22 herein). Each display pixel 22 may include emissive subpixel 62 and thin-film transistor subpixel 64 (also referred to as TFT subpixel 64 herein). Thin-film transistor subpixels 64 are formed within substrate 26. Substrate 26 may include one or more dielectric layers (such as layers 26-1, 26-2, and 26-3) and metallization layers that form the thin-film transistor circuitry (e.g., thin-film transistor subpixels 64) that operates the display. Thin-film transistor subpixels 64 are formed on dielectric layer 26-1. Each thin-film transistor subpixel 64 of each pixel 22 is electrically connected to and controls a respective emissive subpixel 62 of that pixel 22. In the example of FIG. 4, each emissive subpixel 62 includes a respective anode 68 and OLED layers 70 (e.g., a hole injection layer, hole transport layer, an emissive layer, a charge generation layer, an electron transport layer, an electron injection layer, and/or other OLED layers). This example is merely illustrative. In general, each emissive subpixel may be formed using any desired type of display technology (e.g., OLED, LED, LCD, microLED, etc.), and each emissive subpixel may include anodes for the pixels, OLED layers for the pixels, pixel definition layers for the pixels, and/or any other suitable emissive/display layers.

Thin-film transistor subpixels 64 may control the light emitted from the associated emissive subpixel 62 in each pixel 22. Each pixel 22, and therefore each emissive subpixel 62 and thin-film transistor subpixel 64, may be associated with a different color of light (e.g., red, green, and blue). The emissive subpixel for a given pixel does not necessarily need to have the same footprint as its associated thin-film transistor subpixel (e.g., the emissive subpixel may be smaller or larger than the associated thin-film transistor subpixel).

As shown in FIG. 4, each emissive subpixel 62 vertically overlaps (e.g., in the Z-direction) a respective thin-film transistor subpixel 64 by which it is controlled. However, this is merely illustrative. In some embodiments, at least some of pixels 22 may have emissive subpixels 62 that are offset (e.g., in the +X or −X direction) from the associated thin-film transistor subpixel 64.

Sensor 34 may be formed behind (e.g., under) display 14. In other words, sensor 34 may be overlapped by display 14 in the Z-direction. In particular, sensor 34 may receive and/or emit light through display 14. For example, sensor 34 may be an optical sensor, such as a camera, that receives light through display 14. In general, however, sensor 34 may be any suitable sensor that operates through display 14.

Hole 40 (also referred to as window 40, pinhole opening 40, and pinhole 40 herein) may be formed in display 14 and may overlap sensor 34. Hole 40 may be formed by removing one or more TFT subpixels 64. In particular, as shown in FIG. 4, the TFT subpixel of pixel 44 has been removed to form hole 40 to form TFT subpixel-free region 42. The TFT subpixel-free region 42 of hole 40 may allow light to pass without diffracting or distorting the light. However, the emissive subpixel of pixel 44 is still present within hole 40, which may allow display 14 to have a uniform appearance. In this way, hole 40 may be formed to allow sensor 34 to operate through display 14 without sacrificing the appearance of display 14.

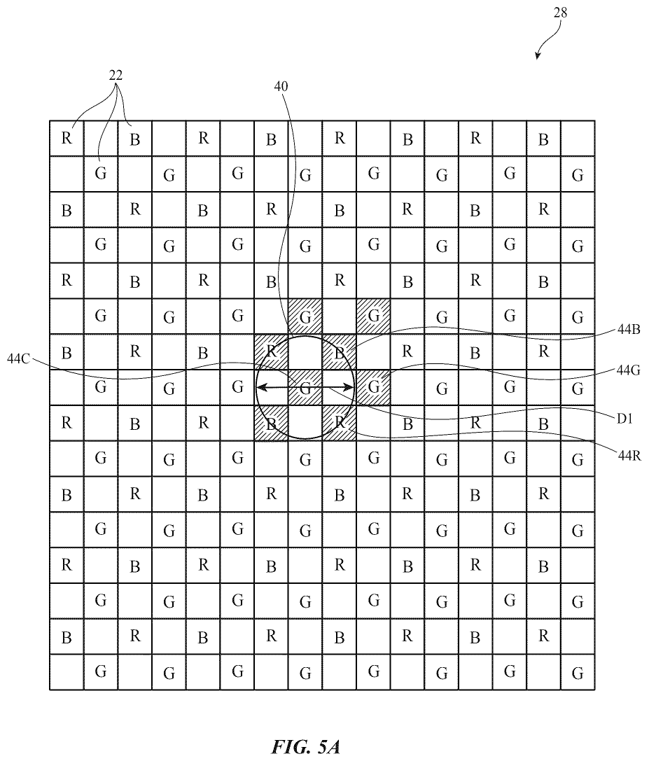

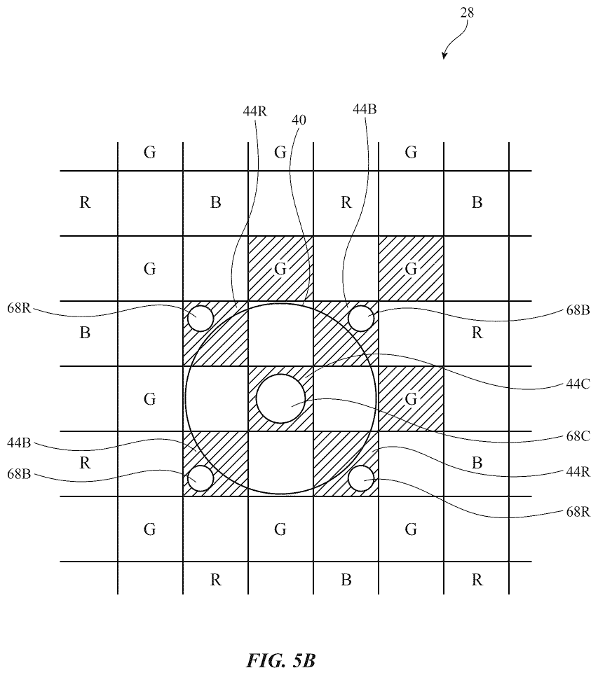

In general, a pinhole opening/window in TFT subpixels 64, such as window 40, may be formed by removing any suitable number of TFT subpixels 64 (e.g., removing a subset of the total number of TFT subpixels 64) to form a TFT-free region. A top view of an illustrative pixel array having a pinhole opening formed by removing multiple TFT subpixels is shown in FIG. 5A.

As shown in FIG. 5A, pixel array 28 may include red, green, and blue pixels 22 labeled R, G, and B, respectively. To form hole 40 for an underlying sensor (e.g., sensor 34 of FIG. 4), the TFT subpixels (e.g., TFT subpixels 64 of FIG. 4) associated with pixels 44 may be removed. In other words, pixels 44 may together form a TFT subpixel-free region that forms hole 40. The absence of TFT subpixels 64 in hole 40 may allow light to pass through display 14 to the underlying sensor. However, some or all of pixels 44 may still include emissive subpixels (e.g., emissive subpixels 62 of FIG. 4), which may allow display 14 to have a uniform appearance.

In the illustrative example of FIG. 5A, hole 40 has been formed by removing the TFT subpixels associated with eight pixels 44. In particular, the TFT subpixels associated with four green pixels 44G, two red pixels 44R, and two blue pixels 44B have been removed. In other words, hole 40 includes a subset of the emissive subpixels that totals eight emissive subpixels. Additionally, central pixel 44C of hole 40 may be a green pixel. However, this is merely illustrative. In general, the TFT subpixels associated with any suitable pixel(s) and any suitable number of pixel(s) across pixel array 28 may be removed to form hole 40, and hole 40 may be formed from a subset of emissive subpixels that totals any suitable number of emissive subpixels.

Hole 40 may have diameter D1, which may be at least 50 microns, at least 70 microns, less than 120 microns, between 50 microns and 90 microns, between 50 microns and 100 microns, between 50 microns and 200 microns, less than 100 microns, less than 200 microns, or another suitable diameter. Although the width of hole 40 is given by diameter D1 in the illustrative example of FIG. 5A in which hole 40 is a circular opening, this is merely illustrative. In general, hole 40 may have any suitable shape, and hole may have a width of at least 50 microns, at least 70 microns, less than 120 microns, between 50 microns and 90 microns, between 50 microns and 100 microns, between 50 microns and 200 microns, less than 100 microns, less than 200 microns, or another suitable width.

Because pixels 44 retain their associated emissive subpixels, including the anodes of the emissive subpixels, pixel array 28 may have a uniform appearance. However, it may be desirable to adjust the anodes of pixels 44 relative to hole 40 to reduce the effects of the anodes on the light that passes through hole 40. An illustrative example is shown in FIG. 5B.

As shown in FIG. 5B, central anode 68C (e.g., a green anode associated with a green emissive subpixel) of central pixel 44C (e.g., a green pixel) of hole 40 may remain in the center of central pixel 44C. However, anodes 68R of pixels 44R and anodes 68B of pixels 44B (e.g., the anodes of the surrounding emissive subpixels-red and blue anodes of red and blue surrounding emissive subpixels in the example of FIG. 5B) may be moved laterally away from central pixel 44C, outside of hole 40. In other words, pixels 44R and 44B (red and blue pixels, respectively, in the illustrative example of FIGS. 5A and 5B) may be surrounding pixels of central pixel 44C within hole 40, and the anodes associated with pixels 44R and 44B (e.g., surrounding anodes of the surrounding emissive subpixels) may be shifted laterally away from central pixel 44C (e.g., the central anode of the central emissive subpixel) to reduce or eliminate the impact of anodes 68R and 68B on the light that passes through hole 40. In this way, the emissive subpixels of pixels 44 may be maintained to improve the uniformity of pixel array 28, but the impact of the emissive subpixels on light that passes through hole 40 may be reduced.

Alternatively or additionally to shifting anodes 68R and 68B laterally away from central pixel 44C, anodes 68R, 68B, 68C, and/or any other suitable anodes (e.g., the central anode of the pinhole, the surrounding anodes of the pinhole, and/or any other suitable anodes) of pixel array 28 may be formed from transparent material. For example, one or more of the anodes may be formed from a transparent conductive oxide, such as indium tin oxide (ITO). In this way, hole 40 may have increased transparency to light, further reducing interference with light that passes through pixel array 28 to an underlying sensor.

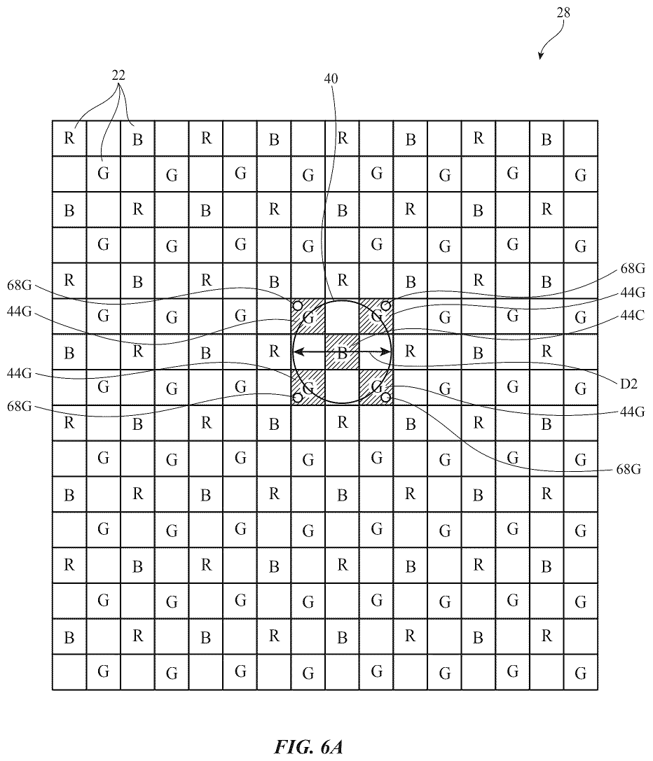

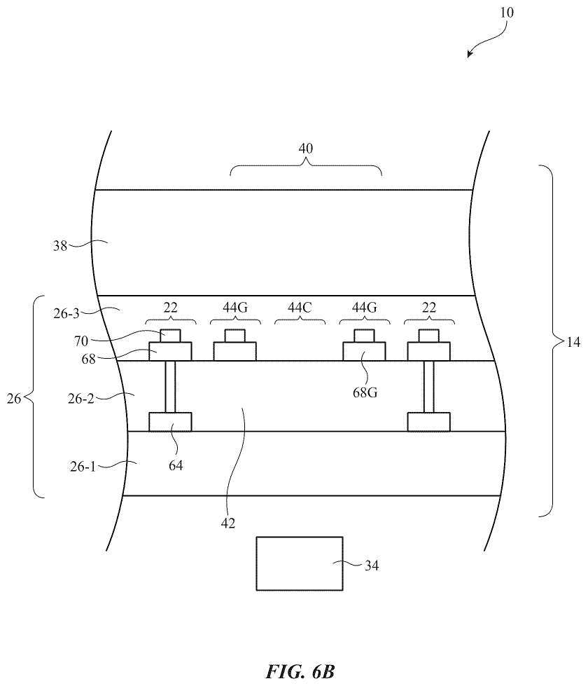

In the illustrative example of FIGS. 5A and 5B, a green pixel is used as central pixel 44C of hole 40, and the TFT subpixels of central pixel 44C and of surrounding red, blue, and green pixels are removed to form hole 40. However, this arrangement is merely illustrative. In some embodiments, a different pixel, such as a blue pixel, may be used as the central pixel of a pinhole opening. An illustrative example is shown in FIG. 6A.

As shown in FIG. 6A, pixel array 28 may include red, green, and blue pixels 22 labeled R, G, and B, respectively. To form hole 40 for an underlying sensor (e.g., sensor 34 of FIG. 4), the TFT subpixels (e.g., TFT subpixels 64 of FIG. 4) associated with pixels 44 may be removed. In other words, pixels 44 may together form a TFT subpixel-free region that forms hole 40. The absence of TFT subpixels 64 in hole 40 may allow light to pass through display 14 to the underlying sensor. However, some or all of pixels 44 may still include emissive subpixels (e.g., emissive subpixels 62 of FIG. 4), which may allow display 14 to have a uniform appearance.

In the illustrative example of FIG. 6A, hole 40 has been formed by removing the TFT subpixels associated with five pixels 44. In particular, the TFT subpixels associated with four green pixels 44G and a central pixel 44C (a blue pixel in the example of FIG. 6A) may be removed. However, this is merely illustrative. In general, the TFT subpixels associated with any suitable pixel(s) and any suitable number of pixel(s) across pixel array 28 may be removed to form hole 40.

Hole 40 may have diameter D2, which may be at least 30 microns, at least 50 microns, less than 70 microns, between 30 and 70 microns, between 50 microns and 100 microns, between 50 microns and 200 microns, less than 100 microns, less than 200 microns, or another suitable diameter. Although the width of hole 40 is given by diameter D2 in the illustrative example of FIG. 6A in which hole 40 is a circular opening, this is merely illustrative. In general, hole 40 may have any suitable shape, and hole 40 may have a width of at least 30 microns, at least 50 microns, less than 70 microns, between 30 and 70 microns, between 50 microns and 100 microns, between 50 microns and 200 microns, less than 100 microns, less than 200 microns, or another suitable width.

Green pixels 44G (or other surrounding pixels around central pixel 44C) may retain their associated emissive subpixels (e.g., green emissive subpixels), including the anodes of the emissive subpixels. In other words, in the example of FIG. 6A, four surrounding pixels that include a subset of four emissive subpixels, may surround central pixel 44C. However, the anode and/or the entire emissive subpixel of central pixel 44C may be removed, if desired. As shown in the illustrative side view of FIG. 6B, pixels 44G may retain anodes 68G (and/or the entirety of emissive subpixels 62), while central pixel 44C may have both the TFT subpixel and the emissive subpixel removed. In this way, pixels 44G and central pixel 44C may form a TFT subpixel-free region that forms pinhole 40, while central pixel 44C additionally forms an emissive subpixel-free region. By removing the anode and/or the entire emissive subpixel of central pixel 44C, pinhole 40 may have sufficient transparency while having a smaller size than in the example of FIG. 5A.

Returning to FIG. 6A, anodes 68G of pixels 44G may be moved laterally away from central pixel 44C, outside of hole 40. In other words, pixels 44G (green pixels in the illustrative example of FIG. 6A) may be surrounding pixels of central pixel 44C within hole 40, and the anodes associated with pixels 44G may be shifted laterally away from central pixel 44C to reduce or eliminate the impact of anodes 68G on the light that passes through hole 40. In this way, the emissive subpixels of pixels 44G may be maintained to improve the uniformity of pixel array 28, but the impact of the emissive subpixels on light that passes through hole 40 may be reduced.

Alternatively or additionally to shifting anodes 68G laterally away from central pixel 44C, anodes 68G and/or any other suitable anodes of pixel array 28 may be formed from transparent material. For example, one or more of the anodes may be formed from a transparent conductive oxide, such as indium tin oxide (ITO). In this way, hole 40 may have increased transparency to light.

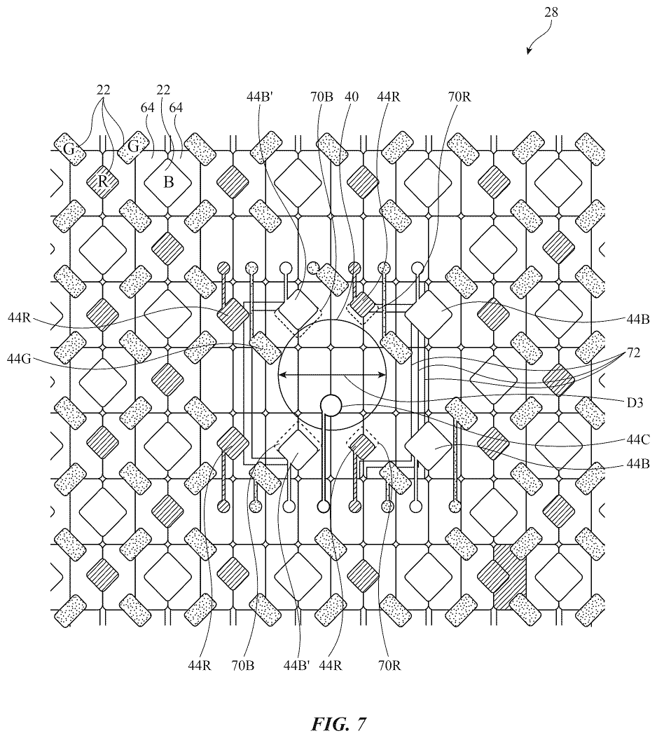

In the examples of FIGS. 5-6, pixel array 28 is illustratively shown as having rectangular red, green, and blue pixels. However, this is merely illustrative. In general, one or more pinholes, such as hole 40, may be formed in a display with any suitable pixels. For example, one or more pinholes may be formed in displays with diamond-shaped pixels (e.g., pixels that are rotated 45° relative to the pixels in FIGS. 5 and 6). Additionally or alternatively, one or more pinhole openings may be formed in displays with additional display layers to those shown in FIGS. 4 and 6B, such as one or more polarizers, one or more color filter layers, one or more masking layers, and/or any other suitable display layers. An illustrative example of a display with a pinhole opening in an alternative pixel layout is shown in FIG. 7.

As shown in FIG. 7, pixel array 28 may include pixels 22. Pixels 22 may include red pixels R, blue pixels B, and green pixels G. As opposed to the rectangular pixels in FIGS. 5-6, pixels 22 in FIG. 7 may have varied shapes. In particular, red pixels R and blue pixels B may have diamond shapes of different sizes, and green pixels G may have rectangular shapes offset an angle relative to red pixels R and blue pixels B. Pixels 22 may include emissive subpixels and TFT subpixels (shown as TFT subpixels 64 in FIG. 7).

Hole 40 may be formed by removing TFT subpixels 64 in and around hole 40. Pixels 44 may include emissive subpixels (e.g., anodes) to improve the uniformity of pixel array 28. However, this is merely illustrative. Some of the pixels 44 may have emissive subpixels removed in addition to having TFT subpixels 64 removed, if desired.

Alternatively or additionally, some of pixels 44 may be adjusted to reduce interference with light that passes through hole 40. For example, blue pixels 44B (e.g., the emissive subpixels associated with blue pixels 44B) may have a reduced footprint relative to standard blue pixel footprint 70B. Similarly, red pixels 44R (e.g., the emissive subpixels associated with red pixels 44R) may have a reduced footprint relative to standard red pixel footprint 70R. In this way, additional space may be made for hole 40, reducing interference with light associated with an underlying sensor.

Central pixel 44C (a green pixel in the illustrative example of FIG. 7) may retain its emissive subpixel (e.g., as shown in FIGS. 4-5), or central pixel 44C may have both its TFT subpixel and emissive subpixel removed (e.g., as shown in FIG. 6).

Although not shown in FIG. 7, additional pixels in and/or around hole 40 may have emissive subpixels and/or TFT subpixels removed, if desired.

Hole 40 may have diameter D3, which may be at least 30 microns, at least 75 microns, at least 80 microns, at least 90 microns, at least 100 microns, between 80 microns and 120 microns, less than 150 microns, between 50 microns and 100 microns, between 50 microns and 200 microns, less than 100 microns, less than 200 microns, or another suitable diameter. Although the width of hole 40 is given by diameter D3 in the illustrative example of FIG. 7 in which hole 40 is a circular opening, this is merely illustrative. In general, hole 40 may have any suitable shape, and hole 40 may have a width of at least 30 microns, at least 75 microns, at least 80 microns, at least 90 microns, at least 100 microns, between 80 microns and 120 microns, less than 150 microns, between 50 microns and 100 microns, between 50 microns and 200 microns, less than 100 microns, less than 200 microns, or another suitable width.

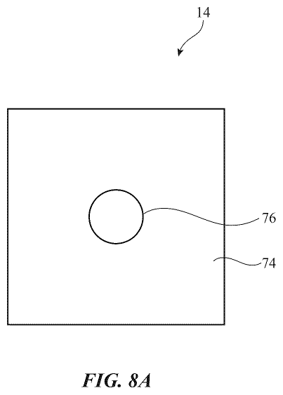

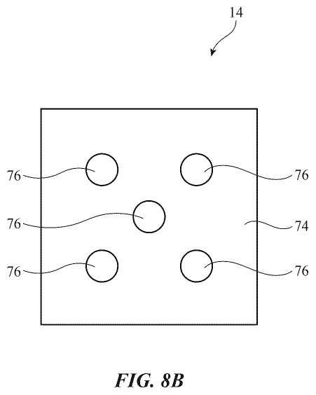

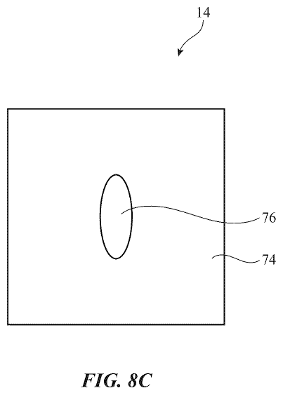

FIGS. 5-7 have shown pixel arrays having a single circular pinhole opening/window/hole. However, this is merely illustrative. In general, a display may include a pixel array with any suitable number of pinhole openings, such as at least one pinhole opening, at least two pinhole openings, at least three pinhole openings, or at least five pinhole openings, as examples, and/or pinhole openings having any suitable shape(s). If a pixel array has multiple pinhole openings, multiple pinhole openings may overlap a single sensor (e.g., sensor 34 of FIGS. 4 and 6B), or a single pinhole opening may be associated with a single sensor. Illustrative examples of pinhole opening patterns and/or shapes that may be used in a display are shown in FIGS. 8A-8C.

As shown in FIG. 8A, display 14 may include region 74 and hole 76 (also referred to as window 76, pinhole opening 76, and pinhole 76 herein). Region 74 may include pixels that have both emissive subpixels and TFT subpixels (e.g., pixels 22 of FIGS. 4-8), while hole 76 may include pixels that do not have TFT subpixels and/or emissive subpixels (e.g., pixels 44 of FIGS. 4-8). In this way, a single, circular hole 76 may be formed in display 14.

As shown in FIG. 8B, display 14 may include five circular holes 76. The five circular holes 76 may be arranged in an array, as shown in FIG. 8B, or holes 76 may be arranged in any other suitable manner. Holes 76 may overlap a single sensor (e.g., sensor 34 of FIGS. 4 and 6B) or multiple sensors.

Including five circular holes 76 in display 14 is merely illustrative, and any number of holes of any desired shape may be incorporated into display 14 and may overlap one or more sensors. For example, FIG. 8C shows an illustrative elliptical hole 78 in display 14. One or more elliptical holes 76 may be included in display 14 and may overlap one or more underlying sensors.

The examples of including circular and/or elliptical holes in a display to overlap a sensor is merely illustrative. One or more holes of any desired shape, such as square holes, rectangular holes, triangular holes, hexagonal holes, octagonal holes, etc. may be included in a display and may be arranged in any suitable pattern to overlap one or more underlying sensors.

In general, a hole, such as pinhole opening 40, may be formed by modifying a subset of any suitable number of pixels, such as at least four pixels, at least five pixels, at least eight pixels, or another suitable number of pixels.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
a plurality of pixels arranged in a light-emitting area, wherein each one of the plurality of pixels includes an emissive subpixel and a thin-film transistor subpixel that controls the emissive subpixel of that pixel;
a hole in the plurality of pixels that includes a subset of the emissive subpixels, including anodes of the subset of the emissive subpixels, and that is free of thin-film transistor subpixels, wherein a central one of the emissive subpixels in the hole comprises a central anode at a center of the hole, and surrounding emissive subpixels of the emissive subpixels in the hole comprise surrounding anodes that are shifted away from the center of the hole; and
an optical sensor that operates through the hole in the plurality of pixels.

2. The electronic device of claim 1, wherein the central anode and the surrounding anodes comprise transparent material.

3. The electronic device of claim 2, wherein the transparent material is a transparent conductive oxide.

4. The electronic device of claim 1, wherein the hole has a width between 50 microns and 200 microns.

5. The electronic device of claim 4, wherein the subset of the emissive subpixels comprises eight emissive subpixels.

6. The electronic device of claim 4, wherein the central one of the emissive subpixels comprises a green emissive subpixel, and the surrounding emissive subpixels comprise red and blue emissive subpixels.

7. The electronic device of claim 1, wherein the hole is formed from removed emissive subpixels and thin-film transistor subpixels, and the hole has a width between 80 microns and 120 microns.

8. A display comprising:
a plurality of pixels arranged in a light-emitting area, wherein each one of the plurality of pixels includes an emissive subpixel and a thin-film transistor subpixel that controls the emissive subpixel of that pixel; and
a window in the plurality of pixels, wherein the window is formed from a subset of the pixels that includes respective emissive subpixels and that does not include thin-film transistor subpixels, and wherein the window is surrounded by other pixels of the plurality of pixels.

9. The display of claim 8, wherein the subset of the pixels comprises at least four pixels.

10. The display of claim 9, wherein the subset of the pixels comprises at least eight pixels.

11. The display of claim 8, wherein the subset of the pixels comprises a central pixel and surrounding pixels, and wherein anodes of the surrounding pixels are shifted laterally away from the central pixel.

12. The electronic device of claim 11, wherein an anode of the central pixel and the anodes of the surrounding pixels comprise transparent material.

13. The display of claim 11, wherein the central pixel comprises a central anode.

14. The display of claim 11, wherein the central pixel is free from an anode.

15. An electronic device comprising:
a display that includes a plurality of pixels arranged in a light-emitting area, wherein each one of the plurality of pixels includes an emissive subpixel and a thin-film transistor subpixel that controls the emissive subpixel of that pixel;
a window in the plurality of pixels, wherein the window is formed from a subset of the pixels that includes respective emissive subpixels with respective anodes and that does not include thin-film transistor subpixels; and
a sensor that operates through the window.

16. The electronic device of claim 15, wherein the window is a hole with a width between 50 microns and 200 microns.

17. The electronic device of claim 15, wherein the window further comprises a central pixel without an anode, and the respective emissive subpixels surround the central pixel.

18. The electronic device of claim 17, wherein the window has a width between 50 microns and 100 microns.

19. The electronic device of claim 18, wherein the respective emissive subpixels comprise four emissive subpixels.

20. The electronic device of claim 18, wherein the central pixel comprises a blue pixel, and the respective emissive subpixels comprise green emissive subpixels.
